(19) United States
(12) Patent Application Publication
(10) Pub. No.: US 2012/0162860 A1
(43) Pub. Date: Jun. 28, 2012

(54) CHIP CAPACITOR AND METHOD OF MANUFACTURING SAME

(75) Inventors: Yutaka Taketani, Osaka (JP); Hitoshi Yoshizawa, Osaka (JP); Kazuo Teraji, Osaka (JP); Naoya Saiki, Osaka (JP)

(73) Assignee: SUN ELECTRONIC INDUSTRIES CORP.

(21) Appl. No.: 13/088,836

(22) Filed: Apr. 18, 2011

(30) Foreign Application Priority Data
Dec. 24, 2010 (JP) 2010-288402

(51) Int. Cl. H01G 4/228; H05K 3/30

(52) U.S. Cl. 361/540; 29/832

(57) ABSTRACT

A chip capacitor (1) includes: a capacitor body (10) from which an anode lead wire (11) and a cathode lead wire (12) are extended out; and a mount portion (20) which is fitted to the capacitor body (10), in which terminal portions (11a and 12a) of the lead wires (11 and 12) are arranged in a board mounting surface (20a) and which is placed on a circuit board. In the chip capacitor (1) in which the terminal portions (11a and 12a) are soldered to the circuit board, the mount portion (20) is formed of a resin containing an organic metal complex compound, and an assistant terminal portion (21) formed by plating a region to which a metal is exposed by applying laser light onto the board mounting surface (20a) is provided.

This application is based on Japanese Patent Application No. 2010-288402 filed on Dec. 24, 2010, the contents of which are hereby incorporated by reference.

### BACKGROUND OF THE INVENTION

1. Field of the Invention

The present invention relates to a chip capacitor that is mounted on the surface of a board and a method of manufacturing such a chip capacitor.

2. Description of Related Art

FIGS. 12 and 13 show a front view and a bottom view of a conventional chip capacitor, respectively. The capacitor 1 includes a capacitor body 10 and a seat plate 20. In the capacitor body 10, an anode lead wire 11 and a cathode lead wire 12 are extended out from an exit surface 10a that is one end surface.

The seat plate 20 is formed with a molded resin product; one surface thereof comes in contact with the exit surface 10a of the capacitor body 10, and the other surface forms a board mounting surface 20a that is placed on a circuit board. In the seat plate 20, there are provided insertion holes 20b through which the lead wires 11 and 12 are inserted. In the board mounting surface 20a, groove portions 20c continuous with the insertion holes 20b are so provided as to form recesses.

The ends of the lead wires 11 and 12 inserted through the insertion holes 20b are bent to form terminal portions 11a and 12a; the terminal portions 11a and 12a are accommodated within the groove portions 20c. Thus, in the capacitor 1, the terminal portions 11a and 12a are arranged in the board mounting surface 20a, and the capacitor 1 is formed as a surface-mount chip capacitor.

Then, solder is applied to the terminal portions 11a and 12a, and the capacitor 1 is mounted on the circuit board by a lead-free reflow process at temperatures of 240° C. to 260° C. Since the seat plate 20 needs to withstand heat produced by the reflow process, the seat plate 20 is formed of heat-resistant resin such as a polyamide.

The capacitor 1 configured as described above is fixed to the circuit board by soldering the terminal portions 11a and 12a of the lead wires 11 and 12. Hence, the lead wires 11 and 12 may be broken such as in a car-mounted application in which strong vibrations are encountered and a high vibration resistance of about 5 G or more is required.

To overcome this problem, there is known a capacitor 1 that has an assistant terminal portion in the board mounting surface 20a of the seat plate 20. FIGS. 14 and 15 show a front cross-sectional view and a bottom view of this seat plate 20, respectively. In addition to the terminal portions 11a and 12a (see FIG. 13), the assistant terminal portion 21 is soldered to the circuit board, and thus it is possible to improve the resistance of the capacitor 1 to vibrations.

The assistant terminal portion 21 is formed by insert-molding into the seat plate 20 a metal plate 22 that is formed in a predetermined shape by bending or the like. By insert-molding the metal plate 22, it is possible to prevent the metal plate 22 from coming off.

Here, it is necessary to maintain the coplanarity of the assistant terminal portion 21 and the board mounting surface 20a. Hence, as shown in FIG. 16, a frame 23 is formed by coupling a plurality of metal plates 22 to a frame member 23a. As indicated by alternate long and short dashed lines, the seat plate 20 is molded by injecting resin into the frame member 23a, and then the frame member 23a is removed.

Japanese Unexamined Utility Model Application Publication No. H02-132926 discloses a capacitor in which an assistant terminal portion connected to lead wires is formed by plating. The assistant terminal portion and the lead wires are fixed to each other so as to be electrically continuous through a solder layer, and they are soldered to a circuit board. In this way, the area of the assistant terminal portion is increased, and thus it is possible to improve the resistance of the capacitor to vibrations.

In a common procedure of forming a terminal by plating, the surface of a seat plate molded of resin is first roughed such as by etching through sandblasting or chemical immersion. Then, the seat plate is immersed in a solution containing catalyst such as tin chloride or palladium chloride, and thus a complex is formed on the roughed surface. Then, the seat plate is immersed in an electroless plating solution containing copper sulfate, copper chloride or the like, and thus a copper base layer is precipitated. Then, the seat plate is immersed in an electroplating solution, and thus a copper plating layer is formed on the base layer. A tin plating layer is then formed on the copper plating layer.

Then, a board mounting surface is patterned by screen printing, and a region where an assistant terminal portion is formed is coated by a resist. The seat plate is then immersed in a predetermined solution, and thus an extra metal plating layer in a portion that is not coated by the resist is chemically dissolved. Then, by removing the resist, the assistant terminal portion formed with the metal plating layer is exposed.

Hence, the surface of the resin is roughed, the metal plating layer is formed and thus the plating layer is mechanically caught in the projections and recesses of the resin, with the result that a high adherence (anchor effect) can be obtained.

However, in the capacitor in which the assistant terminal portion is formed by insert molding, as the material of the metal plate 22, a relatively expensive material, for example, a brass base material that is plated with tin or the like is used. Moreover, since the frame 23 in which a plurality of metal plates 22 are coupled is formed, the insert molding is performed and then the frame member 23a is discarded, the efficiency with which the material is used is reduced to less than 10%. When the insert molding is performed using the frame 23 as the base, the number of seat plates 20 obtained per shot is about a few to ten. Hence, the number of manufacturing steps is increased as compared with a case where a few hundreds of seat plates 20 free from the metal plates 22 shown in FIG. 14 can be molded per shot.

Since the accuracy with which the metal plate 22 is bent is limited, the amount of protrusion D (see FIG. 14) of the assistant terminal portion 21 from the board mounting surface 20a is varied from about 10 to 50 μm. Thus, when cream solder is applied to the circuit board to mount the capacitor 1 on the surface of the board, the capacitor 1 may be inclined, and, when a smaller amount of cream solder is applied, a failure may occur in soldering. Moreover, when the amount of protrusion D is negative due to the wear of a die or the like, and hence the assistant terminal portion 21 is recessed with respect to the board mounting surface 20a, a fatal failure occurs in which it is impossible to perform soldering. Therefore, in order for the amount of protrusion D to be adjusted, the number of manufacturing steps is further increased.

Consequently, when the assistant terminal portion 21 is formed by insert molding, the cost of the capacitor 1 is disadvantageously increased.

On the other hand, in the capacitor in which the assistant terminal portion is formed by plating, even though the area of the assistant terminal portion with respect to the board mounting surface is small, a removal step is required after the plating is performed on a large area. It is also necessary to form a complex after the surface of the seat plate is roughed, and to precipitate a metal that serves as the base of plating. Therefore, the number of steps of manufacturing the seat plate is increased, and the number of manufacturing steps is increased.

Furthermore, since a heat-resistant resin used as the material of the seat plate generally has a high resistance to chemicals and a high mechanical strength, it is almost impossible to rough the surface or it is inefficient to rough the surface. Consequnetly, when the assistant terminal portion is formed by plating, the cost of the capacitor is likewise increased disadvantageously.

### SUMMARY OF THE INVENTION

An object of the present invention is to provide a chip capacitor which has a high resistance to vibrations and in which its cost can be reduced and the quality of soldering can be enhanced, and to provide a method of manufacturing such a chip capacitor.

To overcome the above object, according to the present invention, there is provided a chip capacitor including: a capacitor body from which an anode lead wire and a cathode lead wire are extended out; and a mount portion which is fitted to the capacitor body, in which terminal portions of the lead wires are arranged in a board mounting surface and which is placed on a circuit board. In the chip capacitor in which the terminal portions are soldered to the circuit board, the mount portion is formed of a resin containing an organic metal complex compound, and an assistant terminal portion formed by plating a region to which a metal is exposed by applying laser light onto the board mounting surface is provided.

In this configuration, the anode lead wire and the cathode lead wire are extended out from the capacitor body, and the terminal portions of the lead wires are arranged in the board mounting surface of the mount portion. The assistant terminal portion is formed on the board mounting surface in a step including plating. The terminal portions and the assistant terminal portion are soldered to the circuit board, and thus the chip capacitor is mounted. The mount portion is formed of the resin containing the organic metal complex compound, and the assistant terminal portion is formed by plating the region to which the metal is exposed by applying laser light onto the board mounting surface. The organic metal complex compound is decomposed by applying laser light, the metal is precipitated and the metal is caught in the spongy layer of the resin and serves as the base of plating, with the result that the plating adherence strength is enhanced. The assistant terminal portion and the terminal portions may be electrically continuous with each other or may not be electrically continuous with each other.

In the chip capacitor according to the present invention and configured as described above, the anode lead wire and the cathode lead wires are extended out from the same exit surface of the capacitor body, and a seat plate arranged between the exit surface and the circuit board forms the mount portion. In this configuration, the lead wires extended out from the exit surface of the capacitor body are extended to the board mounting surface opposite the circuit board, and thus the terminal portions are formed.

In the chip capacitor according to the present invention and configured as described above, the seat plate includes an insertion hole through which the lead wires are inserted, the insertion hole is formed such that a peripheral wall is inclined outward toward the circuit board and the assistant terminal portion is provided to extend through the insertion hole. In this configuration, the lead wires pass through the insertion hole and are extended to the board mounting surface, and thus the terminal portions are formed. The peripheral wall of the insertion hole is inclined, thus laser light is easily applied, and the assistant terminal portion is formed to extend through the insertion hole.

In the chip capacitor according to the present invention and configured as described above, the mount portion is arranged on a peripheral surface of the capacitor body, and the board mounting surface is perpendicular to an exit surface of the lead wires. In this configuration, the mount portion is arranged on the peripheral surface of the capacitor body, the lead wires extended out from the exit surface are bent to extend to the board mounting surface and thus the terminal portions are formed. The mount portion may be cylindrical to cover the capacitor body or may be plate-shaped to face one peripheral surface of the capacitor body.

In the chip capacitor according to the present invention and configured as described above, the mount portion includes a groove portion accommodating the terminal portions, and the groove portion is formed such that a wall surface is inclined outward toward the circuit board and the assistant terminal portion is provided to extend through the groove portion. In this configuration, the terminal portions of the lead wires are accommodated within the groove portion, and the terminal portions are arranged on the board mounting surface. The wall surface of the groove portion is inclined, thus laser light is easily applied and the assistant terminal portion is extended and formed into the groove portion.

In the chip capacitor according to the present invention and configured as described above, the assistant terminal portion is formed such that a portion electrically continuous with the anode lead wire and a portion electrically continuous with the cathode lead wire are 1 mm or more apart from each other. In this configuration, the assistant terminal portion is separated such that the portions are 1 mm or more apart from each other, and the assistant terminal portion is electrically continuous with the anode lead wire and the cathode lead wire.

In the chip capacitor according to the present invention and configured as described above, the area of the assistant terminal portion is 80% or less of the area of the board mounting surface.

In the chip capacitor according to the present invention and configured as described above, the heat distortion temperature of the mount portion at a load of 0.455 MPa under ASTM standard D648 is 200° C. or more. In this configuration, the mount portion formed of a heat-resistant resin can be easily plated.

In the chip capacitor according to the present invention and configured as described above, the mount portion is formed by kneading a polyphthalamide and an organic copper complex compound, and the assistant terminal portion is plated with copper.

According to the present invention, there is provided a method of manufacturing a chip capacitor including: a capacitor body from which an anode lead wire and a cathode lead wire are extended out; and a mount portion which is fitted to the capacitor body, in which terminal portions of the lead wires are arranged in a board mounting surface and which is placed on a circuit board. The method, of manufacturing the chip capacitor having the terminal portions soldered to the circuit board, includes: a mount portion formation step of forming the mount portion of a resin containing an organic metal complex compound; a laser light application step of applying laser light to a predetermined region on the board mounting surface to expose a metal; and a plating step of plating the region to which the metal is exposed in the laser light application step and forming an assistant terminal portion that is soldered to a circuit board.

According to this configuration, in the mount portion formation step, the mount portion is formed such as by injecting the resin containing the organic metal complex compound. Then, in the laser light application step, the laser light is applied to the predetermined region on the board mounting surface, and thus the organic metal complex compound is decomposed and the metal is precipitated and exposed. Then, in the plating step, the region to which the metal is exposed in the laser light application step is plated, and thus the assistant terminal portion is formed on the board mounting surface. The lead wires of the capacitor body form the terminal portions on the board mounting surface, and the terminal portions and the assistant terminal portion are soldered to the circuit board, with the result that the chip capacitor is mounted.

According to the present invention, the mount portion including the board mounting surface is formed of the resin containing the organic metal complex compound, and the assistant terminal portion is formed by plating the region to which the metal is exposed by applying laser light onto the board mounting surface. It is therefore possible not only to improve the resistance of the chip capacitor to vibrations by soldering the assistant terminal portion to the circuit board but also to reduce the cost of the chip capacitor by reducing the number of steps of manufacturing the mount portion. Furthermore, the coplanarity can be enhanced, and thus it is possible to enhance the quality of the soldering of the chip capacitor.

### BRIEF DESCRIPTION OF THE DRAWINGS

FIG. 1 is a front view showing a capacitor according to a first embodiment of the present invention;

FIG. 2 is a bottom view showing the seat plate of the capacitor according to the first embodiment of the present invention;

FIG. 3 is a front view showing the seat plate of the capacitor according to the first embodiment of the present invention;

FIG. 4 is a process diagram showing a process of manufacturing the capacitor according to the first embodiment of the present invention;

FIG. 5 is a plan view showing a step of manufacturing a mount portion of the capacitor according to the first embodiment of the present invention;

FIG. 6 is a bottom view showing the seat plate of a capacitor according to a second embodiment of the present invention;

FIG. 7 is a front view showing the seat plate of the capacitor according to the second embodiment of the present invention;

FIG. 8 is a bottom view showing the seat plate of a capacitor according to a third embodiment of the present invention;

FIG. 9 is a front surface view showing the seat plate of the capacitor according to the third embodiment of the present invention;

FIG. 10 is a perspective view showing a capacitor according to a fourth embodiment of the present invention;

FIG. 11 is a bottom view showing a capacitor according to the fourth embodiment of the present invention;

FIG. 12 is a front view showing a conventional capacitor;

FIG. 13 is a bottom view showing the conventional capacitor;

FIG. 14 is a front cross-sectional view showing the seat plate of the conventional capacitor;

FIG. 15 is a bottom view showing the seat plate of the conventional capacitor; and

FIG. 16 is a plan view showing a state of the seat plate of the conventional capacitor at the time of formation.

### DETAILED DESCRIPTION OF PREFERRED EMBODIMENTS

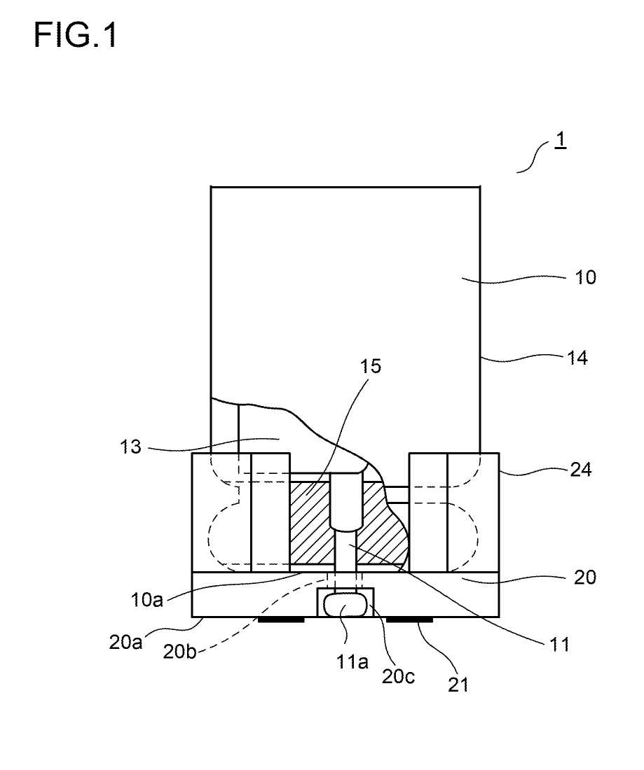

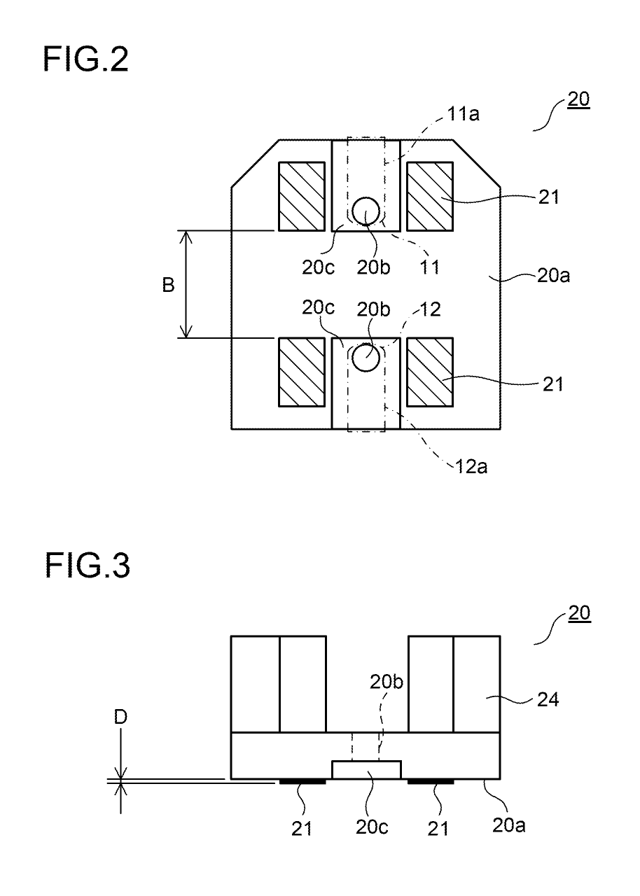

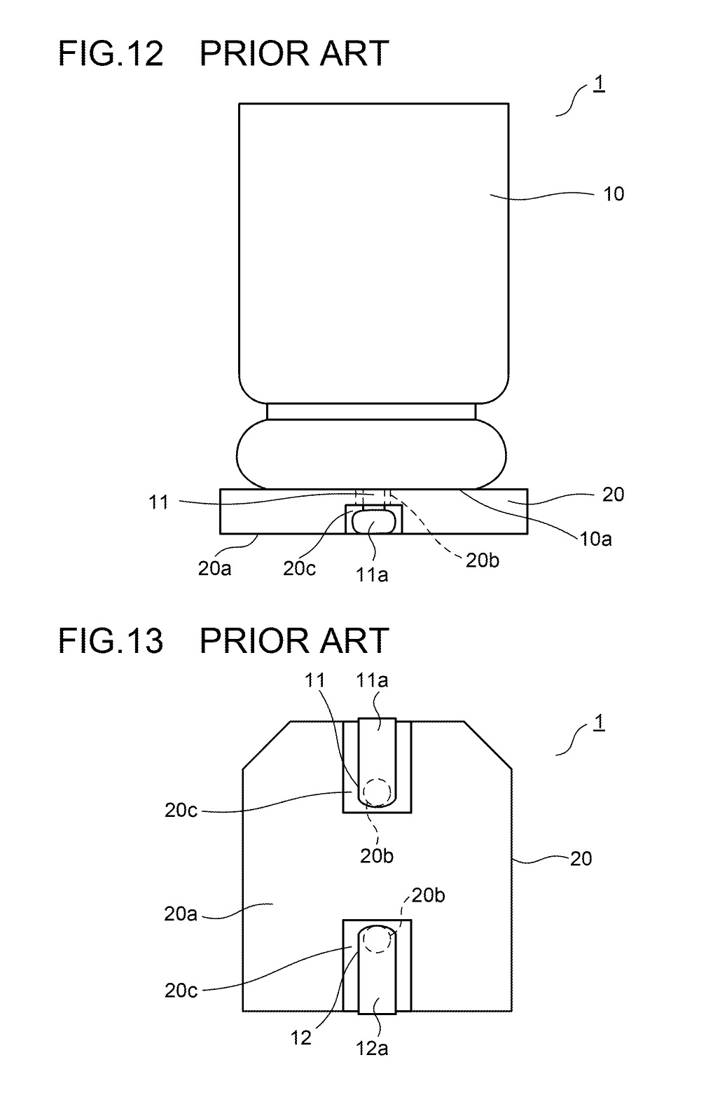

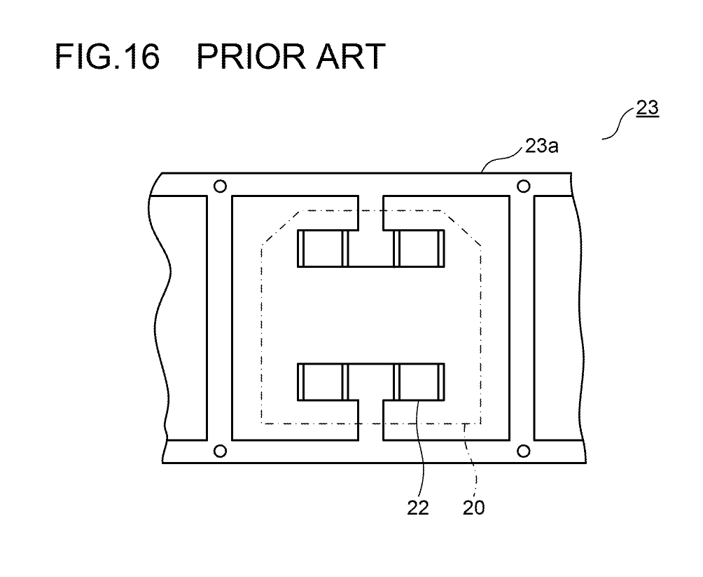

Embodiments of the present invention will be described below with reference to the accompanying drawings. For convenience of description, the same parts as in the conventional example shown in FIGS. 12 to 16 are identified with common reference numerals. FIGS. 1 and 2 show a front view and a bottom view of a chip capacitor according to a first embodiment, respectively. The capacitor 1 includes a capacitor body 10 and a seat plate 20.

In the capacitor body 10, a capacitor element 13 is accommodated within a cylindrical metal case 14 with a bottom, and the opening end of the metal case 14 is sealed with a sealing member 15 such as rubber. The capacitor element 13 is formed by winding an anode foil and a cathode foil (both of which are unillustrated) through a separator (unillustrated) such as capacitor paper. The anode foil is formed with a metal functioning as a valve, such as aluminum, tantalum, niobium or titanium; a dielectric coating is formed on the surface of the anode foil. The cathode foil is arranged opposite the anode foil through the separator, and is formed of aluminum or the like.

A space, including the separator, between the surface of the dielectric coating of the anode foil and the surface of the cathode foil may be impregnated with an electrolyte, or an electroconductive polymer layer may be formed therein. These substantially function as a cathode electrode.

Lead wires 11 and 12 are attached to the anode foil and the cathode foil, respectively. The lead wires 11 and 12 penetrate the sealing member 13 and are extended out from an exit surface 10a that is formed by the surface of the sealing member 13. In this way, the capacitor body 10 is formed in a so-called lead wire terminal same direction shape (JIS C5101-1 shape symbol 04) in which the lead wires 11 and 12 extend in the same direction.

The seat plate 20 is formed with a molded resin product; one surface thereof comes in contact with the exit surface 10a of the capacitor body 10, and the other surface forms a board mounting surface 20a. In the board mounting surface 20a of the seat plate 20, groove portions 20c are so provided as to form recesses. Insertion holes 20b through which the lead wires 11 and 12 are inserted are provided within the groove portions 20c.

The ends of the lead wires 11 and 12 inserted through the insertion holes 20b are bent to form terminal portions 11a and 12a; the terminal portions 11a and 12a are accommodated within the groove portions 20c. Thus, in the capacitor 1, the terminal portions 11a and 12a are arranged in the board mounting surface 20a, and the capacitor 1 is formed in a surface-mount chip shape (JIS C5101-1 shape symbol 32).

On the board mounting surface 20a of the seat plate 20, there are provided assistant terminal portions 21 that are soldered to a circuit board. The assistant terminal portions 21 are formed in a manufacturing process including a plating step as described later. In an example of the present embodiment, the assistant terminal portions 21 are separately arranged on both sides of the terminal portion 11a and on both sides of the terminal portion 12a, that is, are arranged at four locations.

Solder is applied to the terminal portions 11a and 12a and the assistant terminal portions 21, and the capacitor 1 is mounted on the circuit board by a lead-free reflow process at temperatures of 240° C. to 260° C. The seat plate 20 is arranged between the capacitor body 10 and the circuit board, and forms a mount portion that is placed on the circuit board. The assistant terminal portions 21 allow the soldered area to be increased, and thus it is possible to maintain a high resistance of the capacitor 1 to vibrations.

As shown in FIG. 3, support portions 24 that are fitted into the capacitor body 10 are integrally formed at four corners of the seat plate 20. The support portions 24 prevent the capacitor body 10 from shaking with respect to the seat plate 20, and can improve the resistance of the capacitor 1 to vibrations.

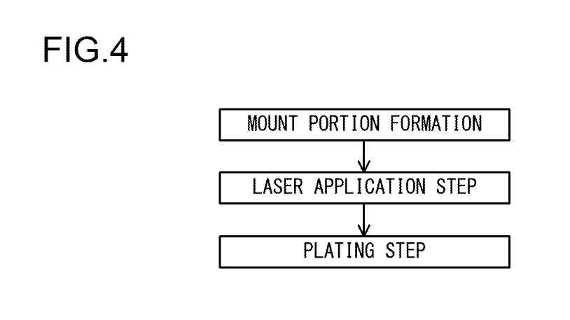

FIG. 4 shows a process of manufacturing the seat plate 20 including the assistant terminal portions 21. In the step of forming the mount portion, the seat plate 20 is formed of a heat-resistant resin that is made of a thermoplastic polymer material containing an organic metal complex compound which is activated by laser light.

As an example of the organic metal complex compound that is activated by laser light, Spinells PK 3095 containing copper, made by Ferro GmbH (see Japanese Patent No. 3881338 and Japanese Unexamined Patent Application Publication No. 2000-503817) or the like can be used.

Since the temperature at the time of reflow soldering ranges from 240° C. to 260° C., the seat plate 20 is required to have such a heat resistance that a heat distortion temperature defined at a load of 0.455 MPa under ASTM standard D648 is 200° C. or more. As this type of heat-resistant resin, an aromatic nylon, polyphthalamide (PPA), polyphenylene sulfide (PPS), a polyamide, a polyimide, a liquid crystal polymer (LCP) or the like can be used.

When the seat plate 20 is measured under UL standard UL94 (2.0 mm thick), it preferably has a flame retardancy equivalent to V0 or V1. Furthermore, since the support portions 24 having the minimum thickness of, for example, 0.4 mm need to hold the capacitor body 10, the seat plate 20 needs to have an impact resistance. Hence, it is preferable to use a resin having an impact strength of 50 J/m or more in the Izod test without notches under ASTM standard D4812 of 3.2 mm width.

Specifically, it is possible to use a commercially available product such as UX08325 made by SABIC (polyphthalamide, heat distortion temperature: 263° C., impact strength: 351 J/m), EXTC0015 made by SABIC (aromatic nylon, heat distortion temperature: 261° C.), 4099×117359D made by RTP Company (polyphthalamide, heat distortion temperature: 279° C.), 299X113399H made by RTP Company (polyamide, heat distortion temperature: 249° C.), 3499-3X113393C made by RTP Company (LCP, heat distortion temperature: 274° C.) or Ultra-amide T4381LDS made by BASF Company (polyamide, heat distortion temperature: 265° C.).

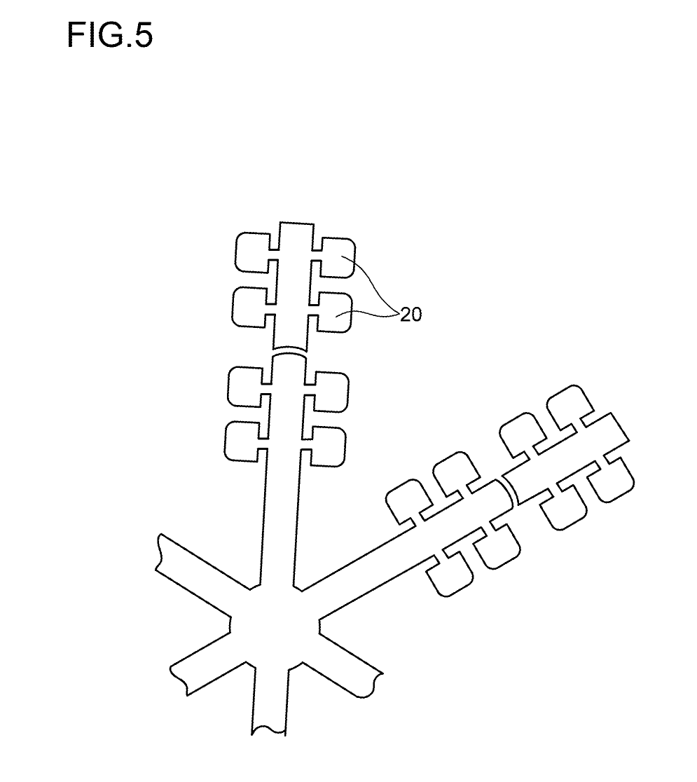

Resin pellets (granules) are formed by previously kneading the heat-resistant resin and a few weight percent of organic metal complex compound, and are injection-molded into the seat plate 20. Here, since insert molding is not involved, as shown in FIG. 5, a large number of seat plates 20 can be formed per shot of molding.

Then, in the step of applying laser light, laser light is applied to regions of the board mounting surface 20a of the seat plate 20 where the assistant terminal portions 21 are formed. Thus, a spongy layer is formed as a result of the resin surfaces of the regions being activated and roughed to become spongy at a depth of about 10 μm. At the same time, the molecules of the organic metal complex compound in the regions are broken, and a metal such as copper is precipitated in the spongy laser and is exposed. The precipitated metal is caught in the spongy layer of the resin, and serves as plating seeds, which will be described later.

When, actually, the outside diameter of the capacitor body 10 was set at 10 mm, the area of the bottom surface of the seat plate 20 was set at 106 mm² (10.3 mm×10.3 mm), the area of the assistant terminal portions 21 was set at 18.7 mm² (1.3 mm×3.6 mm×four locations) and the laser light having a wavelength of 1064 nm was applied, a time period during which the laser light was applied per seat plate 20 was about 0.3 seconds. This time period is about one-third of a time period during which one seat plate 20 is molded by the insert molding in the conventional example. By previously arranging a plurality of seat plates 20, it is possible to process them without human intervention.

Then, in the step of plating, the seat plate 20 is immersed in a chemical reduction plating solution. As the chemical reduction plating solution, for example, a solution of a copper salt such as copper sulfate and a reducing agent such as copper chloride or phosphinate can be used. Hence, the metal exposed in the laser light application step is used as the seeds for forming the metal plating layer such as copper, and the assistant terminal portions 21 are formed on the board mounting surface 20a of the seat plate 20.

In order to enhance the solderability of the metal plating layer such as copper, surface-finishing is performed by a displacement plating method using electroless tin plating or the like. Here, the copper plating may be a few micrometers thick, and the tin plating may be 1 μm or less thick. Thus, the amount of protrusion D (see FIG. 3) of the assistant terminal portion 21 from the board mounting surface 20a is a few micrometers, and it is possible to easily maintain the coplanarity of the assistant terminal portion 21 and the board mounting surface 20a. It is therefore possible to prevent a failure in soldering even if the thickness of cream solder is slightly small.

Since the assistant terminal portions 21 are formed by plating, it is possible to perform a large amount of processing at one time, and consequently the efficiency of the operation is high. Since only the region to which the laser light is applied is selectably plated, it is possible to reduce the amount of plating solution. It is also possible to omit the patterning step using a resist, the step of removing the resist and the step of removing extra plating as shown in the convention example. It is therefore possible not only to reduce the number of steps of manufacturing the seat plate 20 and the capacitor 1 but also to reduce an environmental burden.

The results of a vibration test that was performed on the capacitor 1 configured as described above are shown below. As specimens, three types of chip aluminum electrolytic capacitors having φ10 mm×10.5 mm H (a 30 μF/35 V electrolytic solution-impregnation aluminum electrolytic capacitor, a 220 μF/50 V electrolytic solution-impregnation aluminum electrolytic capacitor and a 33 μF/63 V conductive polymer cathode electrode aluminum electrolytic capacitor) were used. In the seat plate 20, as described above, the area of the bottom surface was 106 mm² (10.3 mm×10.3 mm), and the area of the assistant terminal portions 21 was 18.7 mm².

The capacitor 1 was fixed to a circuit board having a thickness of 1.6 mm by a reflow process using cream solder, and the evaluation test was performed under the following test conditions. The test conditions conformed to a vibration standard AEC-Q200 (its details are shown in parentheses), which was a car-mounted electronic component standard, and were stricter than such a standard.

Test Conditions:

| | | | |
|---|---|---|---|
| Vibration frequency | 5-2000 | Hz | (AEC-Q200: |
| | | | 10-2000 Hz) |
| Maximum acceleration | 30 | G | (AEC-Q200: |
| | | | 5 G) |
| Maximum amplitude | 5 | mm | (AEC-Q200: |
| | | | 1.5 mm) |

| | | |
|---|---|---|
| Testing time | 8 hours for each of X, | (AEC-Q200: |
| | Y and Z directions | 4 hours each) |

The results show that, in a total of 36 specimens of the three types, failures such as discontinuous soldering, broken terminals and unsatisfactory electrical characteristics were not produced. Therefore, they were determined to be satisfactorily and practically fitted into the engine room of an automobile.

The adherence of the capacitor 1 was also tested. Specifically, the capacitor 1 mounted on the circuit board as in the vibration test was peeled in a direction perpendicular to the soldered surface at a rate of 8 mm/minute, and thus the adherence was measured.

Consequently, an average value of 7.4 kg (72.5 N) in ten specimens, which indicated a very high adherence, was observed. The weight of the capacitor 1 having a diameter of 10 mm and including the seat plate 20 is about 1.5 grams, and thus it is possible to sufficiently withstand an impact of 30 G. Here, an area ratio of the assistant terminal portion 21 to the board mounting surface 20a is about 18%, and an adherence for a plating area of 1 mm² is 3.9 N/mm².

After the completion of the test on adherence, when broken portions of the seat plate 20 were observed, broken surfaces of the resin (PPA) itself were observed in about 90% of the area of the assistant terminal portions 21. This reflects a strong adherence between the resin and the metal plating, and this is probably because the metal plating layer is caught in the spongy structure of the resin produced by applying laser light.

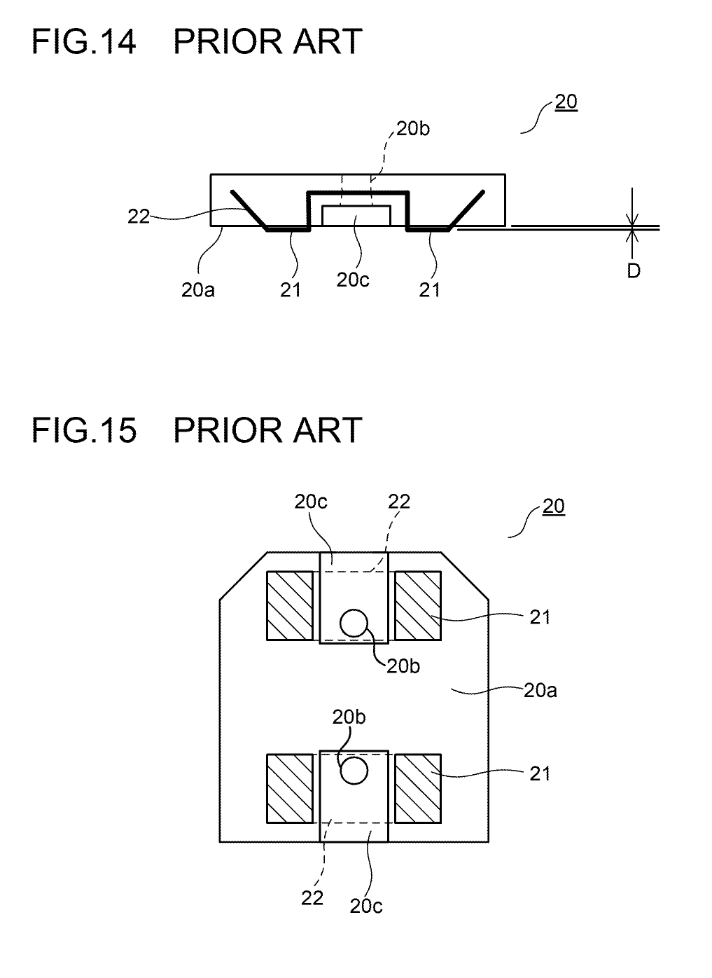

Since the practical peel strength of the capacitor 1 is substantially proportional to an area where the assistant terminal portions 21 are soldered, it is preferable to increase the area of the assistant terminal portions 21. Here, in order to maintain compatibility with the capacitor 1 having the conventional metal plate 22 (see FIG. 14), it is preferable to acquire the maximum area that is allowed by a land pattern on the circuit board.

The assistant terminal portions 21 may be electrically continuous with the lead wires 11 and 12. Here, a portion electrically continuous with the anode lead wire 11 and a portion electrically continuous with the cathode lead wire 12 are formed apart from each other such that a distance B (see FIG. 2) between the portions is equal to or more than 1 mm. Thus, it is possible to reliably prevent a short circuit between the anode lead wire 11 and the cathode lead wire 12.

When the capacitor body 10 has a diameter of 8 mm, the area of the seat plate 20 is small; however, in order to obtain the same peel strength as described above, about the same area of the assistant terminal portions 21 as described above is necessary. Hence, the area of the assistant terminal portions 21 with respect to the area of the board mounting surface 20a is increased. Furthermore, when the height of the capacitor body 10 is great, a high peel strength is needed, and thus it is necessary to increase the area of the assistant terminal portions 21 with respect to the area of the board mounting surface 20a.

Here, when the area of the assistant terminal portions 21 is 80% or more of the area of the board mounting surface 20a, it is difficult to sufficiently separate the assistant terminal portion 21 on the anode side and the assistant terminal portion 21 on the cathode side. Hence, when the area of the assistant terminal portions 21 is set at 80% or less of the area of the board mounting surface 20a, it is possible to easily prevent a short circuit. As compared with the conventional example where the entire board mounting surface 20a is plated and then an unnecessary portion is removed, it is possible to reduce the cost.

According to the present embodiment, the seat plate 20 (mount portion) including the board mounting surface 20a is formed of the resin containing the organic metal complex compound, and the assistant terminal portions 21 are formed by plating the area to which the metal is exposed by applying laser light on the board mounting surface 20a. Thus, it is possible to improve the resistance of the chip capacitor 1 to vibrations by soldering the assistant terminal portions 21 to the circuit board.

Since the metal serving as the base is exposed to the spongy layer by applying laser light, it is possible to omit the conventional step of forming a complex and the step of forming the base layer of plating. It is also possible to omit the step of patterning with the resist, the step of removing the resist and the step of removing an unnecessary portion of plating. It is therefore possible to reduce the number of steps of manufacturing the seat plate 20 and reduce the cost of the chip capacitor 1. Moreover, it is possible to easily maintain the coplanarity of the assistant terminal portion 21 and the board mounting surface 20a, and to prevent a failure in soldering.

Since the anode lead wire 11 and the cathode lead wire 12 are extended out from the same exit surface 10a of the capacitor body 10, and the terminal portions 11a and 12a and the assistant terminal portions 21 are formed in and on the seat plate 20 arranged between the exit surface 10a and the circuit board, it is possible to easily provide the capacitor 1 at a low cost that has a high resistance to vibrations.

Since the heat distortion temperature of the seat plate 20 at a load of 0.455 MPa under ASTM standard D648 is set at 200° C. or more, the seat plate 20 can be practically used in an application in which the seat plate 20 is required to have a heat resistance.

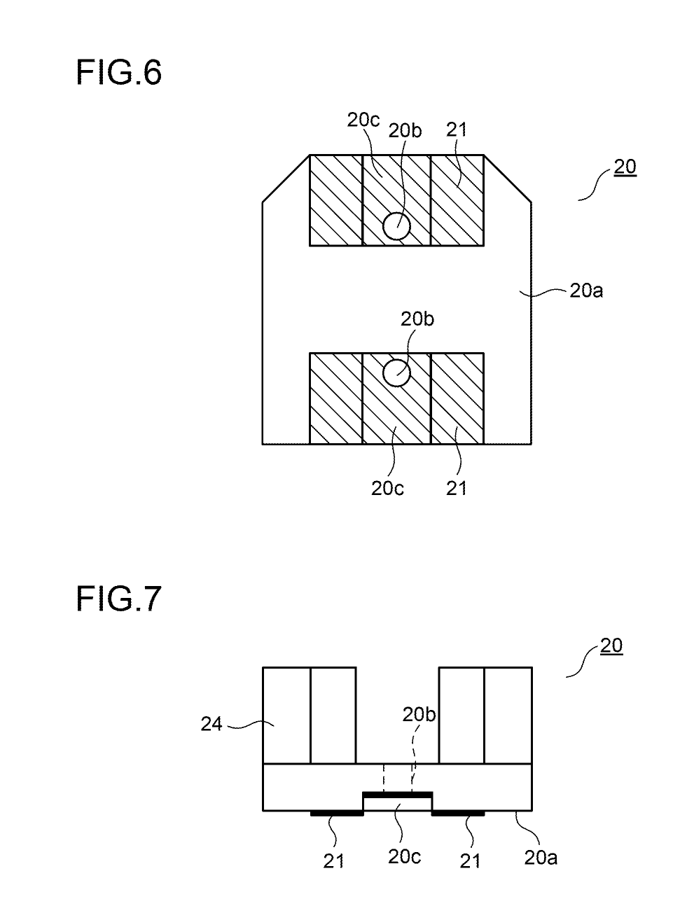

FIGS. 6 and 7 show a bottom view and a front view of the seat plate 20 of a capacitor 1 according to a second embodiment, respectively. For convenience of description, the same parts as in the first embodiment shown in FIGS. 1 to 5 are identified with common reference numerals. In the present embodiment, the assistant terminal portions 21 are formed not only on both sides of the groove portions 20c of the seat plate 20 but also within the groove portions 20c. The other portions are the same as in the first embodiment.

When the capacitor 1 is subjected to a reflow process, solder adheres to the assistant terminal portions 21 within the groove portions 20c through the terminal portions 11a and 12a of the lead wires 11 and 12. Thus, the assistant terminal portions 21 within the groove portions 20c are fixed to the lead wires 11 and 12, and thus it is possible to enhance the fixing strength of the capacitor body 10 and the seat plate 20. It is therefore possible to further improve the resistance of the capacitor 1 to vibrations.

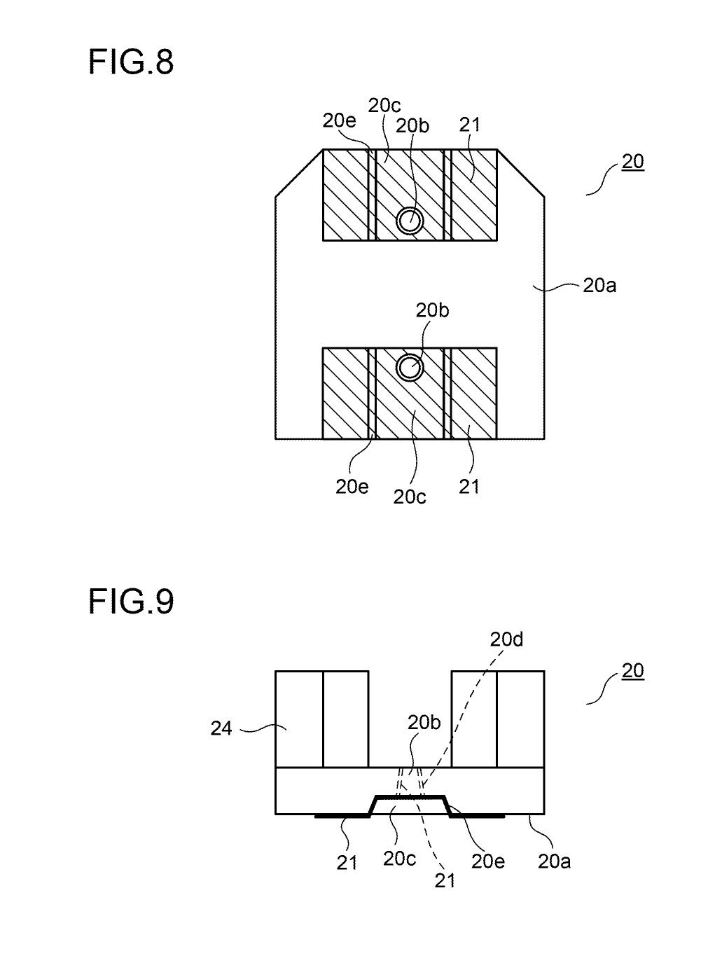

FIGS. 8 and 9 show a bottom view and a front view of the seat plate 20 of a capacitor 1 according to a third embodiment, respectively. For convenience of description, the same parts as in the first embodiment shown in FIGS. 1 to 5 are identified with common reference numerals. In the present embodiment, the assistant terminal portions 21 are provided to extend through not only both side portions of the groove portions 20c of the seat plate 20 but also the insertion holes 20b and the groove portions 20c. The other portions are the same as in the first embodiment.

The insertion hole 20b is formed such that a peripheral wall 20d is inclined outward toward the circuit board; the groove portion 20c is formed such that a wall surface 20e is inclined outward toward the circuit board. Thus, it is possible to easily apply laser light to the peripheral wall 20d and the wall surface 20e in the laser light application step. In this way, in the plating step, the metal plating layers are formed on the peripheral wall 20d and the wall surface 20e. It is therefore possible to provide the assistant terminal portions 21 such that the assistant terminal portions 21 continuously extend through not only both side portions of the groove portions 20c but also the insertion holes 20b and the groove portions 20c. Preferably, the angles at which the peripheral wall 20d and the wall surface 20e are inclined are set at 80 degrees or less so that laser light can be reliably applied.

When the capacitor 1 is subjected to a reflow process, solder adheres to the assistant terminal portions 21 within the insertion holes 20b and the groove portions 20c through the peripheral walls 20d and the wall surfaces 20e. Thus, it is possible to increase the area where the assistant terminal portions 21 are soldered to the circuit board.

In the present embodiment, the area of the assistant terminal portions 21 is 30.2 mm² (4.2 mm×3.6 mm×two locations), and is about 1.6 times as large as that in the first embodiment. An area ratio of the assistant terminal portions 21 to the board reference surface 20a is about 28%. Thus, it is possible to improve the resistance of the capacitor 1 to vibrations.

With the present embodiment, it is possible to obtain the same effects as in the first embodiment. Moreover, since the peripheral walls 20d of the insertion holes 20b are inclined and the assistant terminal portions 21 are provided to extend through the insertion holes 20b, the area where the assistant terminal portions 21 are soldered is increased and thus it is possible to improve the resistance of the capacitor 1 to vibrations. Likewise, since the wall surfaces 20e of the groove portions 20c are inclined and the assistant terminal portions 21 are provided to extend through the groove portions 20c, the area where the assistant terminal portions 21 are soldered is increased and thus it is possible to improve the resistance of the capacitor 1 to vibrations.

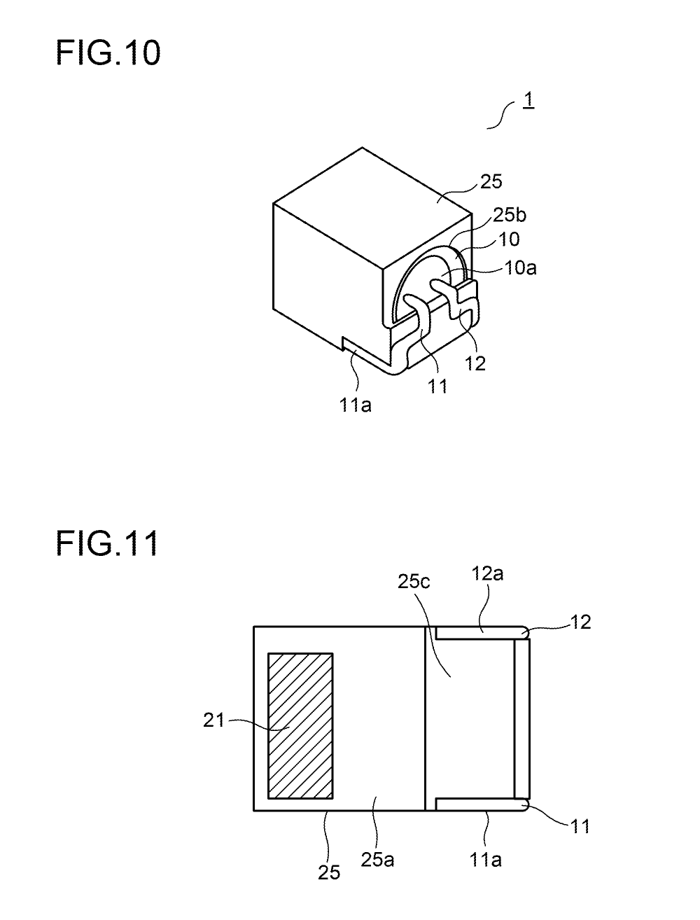

FIGS. 10 and 11 show a perspective view and a bottom view of a capacitor 1 of a fourth embodiment, respectively. For convenience of description, the same parts as in the first embodiment shown in FIGS. 1 to 5 are identified with common reference numerals. The capacitor 1 of the present embodiment has the same capacitor body 10 as in the first embodiment, and is formed in the shape of JIS C5101-1 shape symbol 88 in which the board mounting surface 25a is perpendicular to the exit surface 10a.

The peripheral surface of the capacitor body 10 is covered with a cylindrical outside cover 25 that has an opening portion 25b opposite the exit surface 10a. The lead wires 11 and 12 extended out from the exit surface 10a are bent along the peripheral surfaces of the outside cover 25. Thus, the lead wires 11 and 12 are arranged within a groove portion 25c provided in an end portion in one peripheral surface of the outside cover 25, and the terminal portions 11a and 12a are formed on the board mounting surface 25a. Therefore, the outside cover 25 forms a mount portion that is arranged between the peripheral surface of the capacitor body 10 and the circuit board and that is placed on the circuit board.

On the board mounting surface 25a, the same assistant terminal portion 21 as in the first embodiment is formed. As with the seat plate 20 (see FIG. 1) of the first embodiment, the outside cover 25 that forms the mount portion including the assistant terminal portion 21 is formed of the resin containing the organic metal complex compound. As in the first embodiment, the assistant terminal portion 21 is formed in the laser light application step and the plating step.

Hence, as in the first embodiment, the outside cover 25 (mount portion) including the board mounting surface 25a is formed of the resin containing the organic metal complex compound, and the assistant terminal portion 21 is formed by plating the area to which the metal is exposed by applying laser light onto the board mounting surface 25a. Thus, it is possible to improve the resistance of the chip capacitor 1 to vibrations by soldering the assistant terminal portion 21 to the circuit board.

The conventional step of forming the complex, the step of forming the base layer of plating, the step of patterning with the resist, the step of removing the resist and the step of removing an unnecessary portion of plating are not necessary. It is therefore possible to reduce the number of steps of manufacturing the outside cover 25 and reduce the cost of the chip capacitor 1.

When the chip capacitor formed in the shape of JIS C5101-1 shape symbol 88 is subjected to a reflow process, the terminal portions 11a and 12a are pulled by the weight of solder wicking along the lead wires 11 and 12. Hence, a phenomenon (called Manhattan phenomenon or tombstone phenomenon) occurs in which the end portion on the opposite side to the terminal portions 11a and 12a is raised, and a failure in soldering may be encountered. However, the provision of the assistant terminal portion 21 can prevent the Manhattan phenomenon.

When the area of the assistant terminal portion 21 is increased, it is possible to increase the peel strength of the capacitor 1. Here, as described previously, a portion of the assistant terminal portion 21 electrically continuous with the anode lead wire 11 and a portion thereof electrically continuous with the cathode lead wire 12 are preferably arranged apart from each other such that the distance B between the portions is equal to or more than 1 mm. The assistant terminal portion 21 may extend through the groove portion 25c.

Although, in the present embodiment, the cylindrical outside cover 25 covering the capacitor body 10 is provided with the board mounting surface 25a, and thus the mount portion is formed, a plate-shaped mount portion is arranged on the peripheral surface of the capacitor body 10, and thus the board mounting surface 25a may be provided.

Although, in the first to fourth embodiments, the step of plating the seat plate 20 and the outside cover 25 is performed by chemical plating, it may be performed by electroplating (electrolytic plating).

The present invention can be applied to a chip capacitor that is mounted on the surface of a board.

What is claimed is:

1. A chip capacitor comprising:
a capacitor body from which an anode lead wire and a cathode lead wire are extended out; and
a mount portion which is fitted to the capacitor body, in which terminal portions of the lead wires are arranged in a board mounting surface and which is placed on a circuit board,
wherein the terminal portions are soldered to the circuit board,
the mount portion is formed of a resin containing an organic metal complex compound, and
an assistant terminal portion formed by plating a region to which a metal is exposed by applying laser light onto the board mounting surface is provided.

2. The chip capacitor of claim 1,
wherein the anode lead wire and the cathode lead wires are extended out from a same exit surface of the capacitor body, and a seat plate arranged between the exit surface and the circuit board forms the mount portion.

3. The chip capacitor of claim 2,
wherein the seat plate includes an insertion hole through which the lead wires are inserted, the insertion hole is formed such that a peripheral wall is inclined outward toward the circuit board and the assistant terminal portion is provided to extend through the insertion hole.

4. The chip capacitor of claim 1,
wherein the mount portion is arranged on a peripheral surface of the capacitor body, and the board mounting surface is perpendicular to an exit surface of the lead wires.

5. The chip capacitor of claim 1,
wherein the mount portion includes a groove portion accommodating the terminal portions, and the groove portion is formed such that a wall surface is inclined outward toward the circuit board and the assistant terminal portion is provided to extend through the groove portion.

6. The chip capacitor of claim 1,
wherein the assistant terminal portion is formed such that a portion electrically continuous with the anode lead wire and a portion electrically continuous with the cathode lead wire are 1 mm or more apart from each other.

7. The chip capacitor of claim 1,
wherein an area of the assistant terminal portion is 80% or less of an area of the board mounting surface.

8. The chip capacitor of claim 1,
wherein a heat distortion temperature of the mount portion at a load of 0.455 MPa under ASTM standard D648 is 200° C. or more.

9. The chip capacitor of claim 1,
wherein the mount portion is formed by kneading a polyphthalamide and an organic copper complex compound, and the assistant terminal portion is plated with copper.

10. A method of manufacturing a chip capacitor including:
a capacitor body from which an anode lead wire and a cathode lead wire are extended out; and
a mount portion which is fitted to the capacitor body, in which terminal portions of the lead wires are arranged in a board mounting surface and which is placed on a circuit board,
the terminal portions being soldered to the circuit board, the method comprising:
a mount portion formation step of forming the mount portion of a resin containing an organic metal complex compound;
a laser light application step of applying laser light to a predetermined region on the board mounting surface to expose a metal; and
a plating step of plating the region to which the metal is exposed in the laser light application step to form an assistant terminal portion that is soldered to a circuit board.
